(19) United States
(12) Patent Application Publication
(10) Pub. No.: US 2024/0324355 A1
(43) Pub. Date: Sep. 26, 2024

(54) DISPLAY DEVICE

(71) Applicant: Samsung Display Co., Ltd., Yongin-Si (KR)

(72) Inventors: Shinmoon Kang, Yongin-si (KR); Guanghai Jin, Yongin-si (KR)

(21) Appl. No.: 18/600,781

(22) Filed: Mar. 11, 2024

(30) Foreign Application Priority Data
Mar. 24, 2023 (KR) 10-2023-0039166
Jun. 15, 2023 (KR) 10-2023-0077009

(51) Int. Cl. H10K 59/131; H10K 59/38

(52) U.S. Cl. CPC H10K 59/131; H10K 59/38

(57) ABSTRACT

A display device includes a first substrate including a unit area in which a first pixel circuit, a second pixel circuit, and a third pixel circuit are arranged, a first common voltage line and a second common voltage line arranged in parallel with the unit area therebetween, an auxiliary electrode disposed on the first common voltage line and electrically connected to the first common voltage line, and a preliminary electrode disposed on the second common voltage line.

### CROSS-REFERENCE TO RELATED APPLICATION

This application is based on and claims priority, under 35 U.S.C. § 119, to Korean Patent Application No. 10-2023-0039166 filed on Mar. 24, 2023 in the Korean Intellectual Property Office, and to Korean Patent Application No. 10-2023-0077009 filed on Jun. 15, 2023 in the Korean Intellectual Property Office, the disclosures of which are incorporated by reference herein in their entirety.

### BACKGROUND

### 1. Field

One or more embodiments relate to a display device.

### 2. Description of the Related Art

As the field of display visually expressing various electrical signal information develops rapidly, various types of display devices having excellent characteristics such as thinness, light weight, low power consumption, and the like have been introduced.

A display device may include a liquid crystal display device that does not emit light by itself but uses light from a backlight, and a light-emitting display device that includes a display element capable of emitting light. The light-emitting display device may include display elements, each including a pixel electrode, an emission layer, and a counter electrode.

### SUMMARY

When defects occur in some display elements, the visibility of images displayed by a display device may be deteriorated.

Provided is a display device that displays a high-quality image. However, such an objective is an example, and the scope of the disclosure is not limited thereby.

Additional aspects will be set forth in part in the description which follows and, in part, will be apparent from the description, or may be learned by practice of the presented embodiments of the disclosure.

According to an aspect of the disclosure, a display device includes a first substrate including a unit area in which a first pixel circuit, a second pixel circuit, and a third pixel circuit are arranged, a first common voltage line and a second common voltage line arranged in parallel with the unit area therebetween, an auxiliary electrode disposed on the first common voltage line and electrically connected to the first common voltage line, and a preliminary electrode disposed on the second common voltage line.

The display device may further include a pixel defining layer disposed on the auxiliary electrode and the preliminary electrode, wherein an auxiliary opening exposing a part of the auxiliary electrode and a preliminary opening exposing a part of the preliminary electrode are defined in the pixel defining layer.

The display device may further include an intermediate layer disposed on the pixel defining layer and in the auxiliary opening, a counter electrode disposed on the intermediate layer, and a through-hole extending through the intermediate layer in the auxiliary opening.

The counter electrode may be electrically connected to the auxiliary electrode through the through-hole.

The intermediate layer may include an emission layer arranged to correspond to the preliminary electrode.

The emission layer and the auxiliary electrode are disposed on mutually exclusive parts of the first substrate.

The display device may further include a first pixel electrode arranged in the unit area, wherein the first pixel circuit may be electrically connected to one of the first pixel electrode and the preliminary electrode.

The area of the first pixel electrode may be greater than the area of the preliminary electrode.

The area of the preliminary electrode may be greater than the area of the auxiliary electrode.

The auxiliary electrode and the preliminary electrode may be each provided in plural, and one or more preliminary electrodes may be arranged between two neighboring auxiliary electrodes.

The display device may further include an auxiliary common voltage line electrically connected to the first common voltage line and the second common voltage line and disposed on the first common voltage line and the second common voltage line.

The first common voltage line and the second common voltage line may extend in a first direction, the auxiliary common voltage line may extend in a second direction crossing the first direction, and the first common voltage line and the second common voltage line may form a mesh structure with the auxiliary common voltage line.

The display device may further include a first pixel electrode electrically connected to the first pixel circuit, and a preliminary pixel circuit arranged in the unit area.

The preliminary electrode may be electrically connected to the preliminary pixel circuit.

According to one or more embodiments, a display device includes:

a light-emitting panel including light-emitting diodes, and a color panel disposed on the light-emitting panel and converting or transmitting light emitted from the light-emitting diodes, wherein the light-emitting panel may include a first substrate including a unit area in which a first pixel circuit, a second pixel circuit, and a third pixel circuit are arranged, a first common voltage line and a second common voltage line arranged in parallel with the unit area therebetween, an auxiliary electrode disposed on the first common voltage line and electrically connected to the first common voltage line, and a preliminary electrode disposed on the second common voltage line.

The display device may further include a pixel defining layer disposed on the auxiliary electrode and the preliminary electrode, wherein an auxiliary opening exposing a part of the auxiliary electrode and a preliminary pixel opening exposing a part of the preliminary electrode are defined in the pixel defining layer.

The display device may further include an intermediate layer disposed on the pixel defining layer, a counter electrode disposed on the intermediate layer, and a through-hole extending through the intermediate layer in the auxiliary opening.

The counter electrode may be electrically connected to the auxiliary electrode through the through-hole.

The display device may further include a first pixel electrode arranged in the unit area, wherein the first pixel circuit may be electrically connected to the first pixel electrode or the preliminary electrode.

In an embodiment, the color panel may include a second substrate, a first color conversion portion disposed on the second substrate and arranged to correspond to the first pixel electrode, and a preliminary color conversion portion arranged to correspond to the preliminary electrode, and the first color conversion portion and the preliminary color conversion portion may convert incident blue light into green light.

Other aspects, features, and advantages than those described above will become apparent from the following drawings, claims, and detailed description of the disclosure

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display device according to an embodiment;

FIG. 2 is a schematic cross-sectional view of the display device of FIG. 1 taken along line I-I′;

FIG. 3 is a view for explaining a color conversion-transmission layer of FIG. 2;

FIG. 4 is an equivalent circuit diagram of one pixel included in a display device according to an embodiment;

FIG. 5 is a plan view of common voltage lines and auxiliary common voltage lines of a display device according to an embodiment;

FIG. 6 is a schematic layout diagram of an arrangement of a common voltage line and a pixel electrode of a display device according to an embodiment;

FIG. 7 is a schematic layout diagram of a display device according to an embodiment;

FIG. 8 is a schematic cross-sectional view of the display device of FIG. 7 taken along line II-II′;

FIGS. 9 and 10 are schematic cross-sectional views of the display device of FIG. 6 taken along line IV-IV′;

FIG. 11 is a schematic layout diagram of an arrangement of a common voltage line and a pixel electrode of a display device according to an embodiment; and

FIGS. 12A and 12B are schematic cross-sectional views of a display device according to embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Various modifications may be applied to the present embodiments, and particular embodiments will be illustrated in the drawings and described in the detailed description section. The effect and features of the present embodiments, and a method to achieve the same, will be clearer referring to the detailed descriptions below with the drawings. However, the present embodiments may be implemented in various forms, not by being limited to the embodiments presented below.

Hereinafter, exemplary embodiments will be described in detail with reference to the accompanying drawings, and in the description with reference to the drawings, the same or corresponding constituents are indicated by the same reference numerals and redundant descriptions thereof are omitted.

In the specification, it will be understood that although the terms first, second, etc. may be used herein to describe various elements, these elements should not be limited by these terms. These elements are only used to distinguish one element from another.

In the specification, as used herein, the singular forms “a,” “an,” and “the” are intended to include the plural forms as well, unless the context clearly indicates otherwise.

In the specification, it will be further understood that the terms “comprises” and/or “comprising” used herein specify the presence of stated features or elements, but do not preclude the presence or addition of one or more other features or components.

In the specification, it will be understood that when an element, such as a layer, a film, a region, or a plate, is referred to as being “on” another element, the element can be directly on the other element or intervening elements may be present thereon.

In the specification, it will be understood that when a layer, region, or element is referred to as being “connected to” another layer, region, or element, it can be directly connected to the other layer, region, or component or indirectly connected to the other layer, region, or component via intervening layers, regions, or components. For example, in the specification, when a layer, region, or component is referred to as being electrically connected to another layer, region, or component, it can be directly electrically connected to the other layer, region, or component or indirectly electrically connected to the other layer, region, or component via intervening layers, regions, or components.

In the specification, “the expression such as “A and/or B” may include A, B, or A and B. The expression such as “at least one of A and B” may include A, B, or A and B.

In the specification, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

In the specification, when a certain embodiment may be implemented differently, a specific process order may be performed differently from the described order. For example, two consecutively described processes may be performed substantially at the same time or performed in an order that is the reverse of the order described.

Sizes of elements in the drawings may be exaggerated for convenience of explanation. For example, since sizes and thicknesses of elements in the drawings are arbitrarily illustrated for convenience of explanation, the following embodiments are not limited thereto.

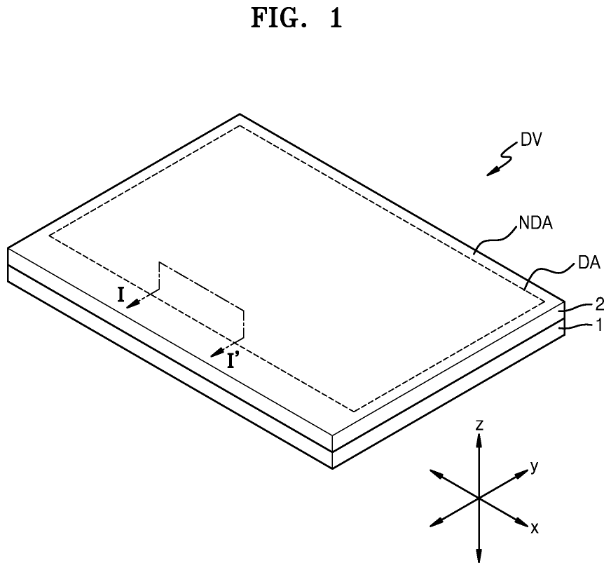

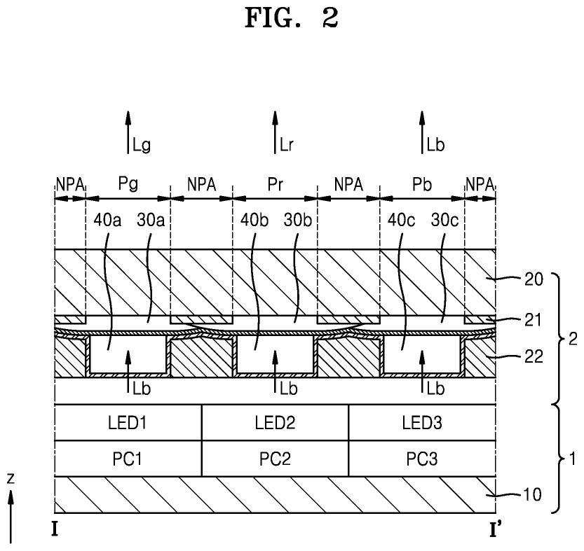

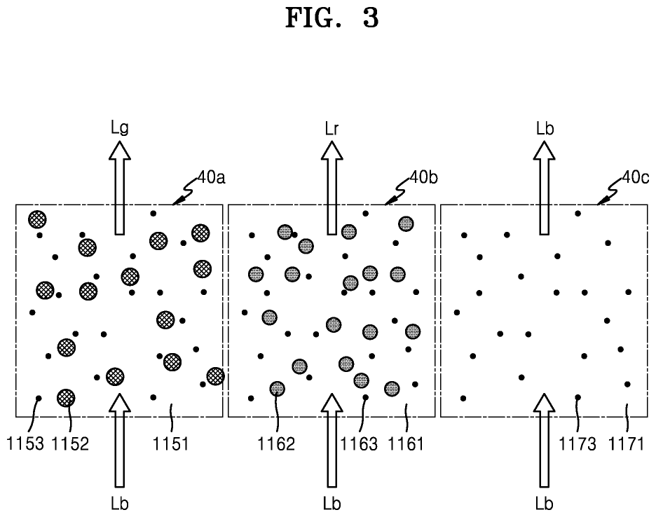

FIG. 1 is a schematic perspective view of a display device DV according to an embodiment. FIG. 2 is a schematic cross-sectional view of the display device DV of FIG. 1 taken along line I-I′. FIG. 3 is a view for explaining a color conversion-transmission layer of FIG. 2.

Referring to FIG. 1, the display device DV may include a display area DA and a non-display area NDA outside the display area DA. The display device DV may provide an image through an array of a plurality of pixels arranged two-dimensionally on an x-y plane of the display area DA.

Each pixel is an area for emitting light of a certain color, and the display device DV may provide an image using the light emitted from the pixels. For example, each pixel may emit red, green, or blue light.

The non-display area NDA, which is an area that does not provide an image, may entirely surround the display area DA. A driver or main power line for providing electrical signals or power to pixel circuits may be arranged in the non-display area NDA. The non-display area NDA may include a pad that is an area to which electronic devices or printed circuit boards may be electrically connected.

The display area DA, as illustrated in FIG. 1, may have a polygonal shape including a rectangle. For example, the display area DA may have a rectangular shape in which the horizontal length is greater than the vertical length, a rectangular shape in which the horizontal length is less than the vertical length, or a square shape. Alternatively, the display area DA may have various shapes such as an oval or a circle.

In some embodiments, the display device DV may include a light-emitting panel 1 and a color panel 2 stacked in the thickness direction (e.g., z direction) thereof. Referring to FIG. 2, the light-emitting panel 1 may include first to third pixel circuits PC1, PC2, and PC3 on a first substrate 10, and first to third light-emitting diodes LED1, LED2, and LED3 respectively connected to first to third pixel circuits PC1, PC2, and PC3.

While passing through the color panel 2, light (e.g., blue light Lb) emitted from the first to third light-emitting diodes LED1, LED2, and LED3 may be either converted into red light Lr, green light Lg, and blue light Lb or transmitted. An area from which the red light Lr is emitted may correspond to a red pixel Pr, an area from which the green light Lg is emitted may correspond to a green pixel Pg, and an area from which the blue light Lb is emitted may correspond to a blue pixel Pb.

The color panel 2 may include a color conversion-transmission layer including a first color conversion portion 40a, a second color conversion portion 40b, and a transmission portion 40c, and a color layer including a first color filter 30a, a second color filter 30b, and a third color filter 30c.

In the color panel 2, a first color area may include the first color conversion portion 40a and the first color filter 30a overlapping each other, a second color area may include the second color conversion portion 40b and the second color filter 30b overlapping each other, and a third color area may include the transmission portion 40c and the third color filter 30c overlapping each other.

The color panel 2 may include a light shielding area arranged to surround each of the first to third color areas. The light shielding area may include a first light shielding layer 21 on a second substrate 20. The first light shielding layer 21 may include a plurality of holes that are formed as portions corresponding to the red pixel Pr, the green pixel Pg, and the blue pixel Pb are removed. The first light shielding layer 21 may include a material portion located in a non-pixel area NPA, and the material portion may include various materials capable of absorbing light.

The light shielding area may include the second light shielding layer 22 on the first light shielding layer 21. A second light shielding layer 22 may also include the material portion located in the non-pixel area NPA. The second light shielding layer 22 may include various materials capable of absorbing light. The second light shielding layer 22 may include the same material as or a material different from the material of the first light shielding layer 21, as described above. The first light shielding layer 21 and/or the second light shielding layer 22 may include an opaque inorganic insulating material such as a chromium oxide, a molybdenum oxide, or the like, or an opaque organic insulating material such as black resin or the like.

The blue light Lb emitted from the first light-emitting diode LED1 of the light-emitting panel 1 may pass through the first color area of the color panel 2. While passing through the color panel 2, the blue light Lb may be converted and filtered into the green light Lg. The first color conversion portion 40a and the first color filter 30a provided in the first color area may be arranged to overlap the first light-emitting diode LED1. The blue light Lb emitted from the first light-emitting diode LED1 may be converted in the first color conversion portion 40a and then pass through the first color filter 30a.

The blue light Lb incident on the first color conversion portion 40a may be converted into the green light Lg. The first color conversion portion 40a may include, as illustrated in FIG. 3, a first photosensitive polymer 1151, and first quantum dots 1152 and first scattering particles 1153 dispersed in the first photosensitive polymer 1151.

The first quantum dots 1152 may be excited by the blue light Lb and may isotropically emit the green light Lg having a wavelength greater than that of the blue light Lb. The first photosensitive polymer 1151 may include an organic material having light transmission. The first scattering particles 1153 may scatter the blue light Lb that is not absorbed by the first quantum dots 1152 so as to excite more first quantum dots 1152, thereby increasing color conversion efficiency. The first scattering particles 1153 may include, for example, a titanium oxide (TiO₂), a metal particle, or the like. The first quantum dots 1152 may be selected from among a Group II-VI compound, a Group III-V compound, a Group IV-VI compound, a Group IV element, a Group IV compound, and a combination thereof.

While passing through the first color filter 30a, the color purity of the green light Lg converted by the first color conversion portion 40a may be improved. The first color filter 30a may include a pigment or dye of a first color (e.g., green).

The blue light Lb emitted from the second light-emitting diode LED2 of the light-emitting panel 1 may pass through the second color area of the color panel 2. While passing through the color panel 2, the blue light Lb may be converted and filtered into the red light Lr. The second color conversion portion 40b and the second color filter 30b provided in the second color area may be arranged to overlap the second light-emitting diode LED2. The blue light Lb emitted from the second light-emitting diode LED2 may be converted in the second color conversion portion 40b, and then may pass through the second color filter 30b.

The second color conversion portion 40b may convert the blue light Lb that is input into the red light Lr. The second color conversion portion 40b may be arranged to overlap the second color filter 30b. The second color conversion portion 40b may include, as illustrated in FIG. 3, a second photosensitive polymer 1161, and second quantum dots 1162 and second scattering particles 1163 dispersed in the second photosensitive polymer 1161.

The second quantum dots 1162 may be excited by the blue light Lb and may isotropically emit the red light Lr having a wavelength greater than the wavelength of the blue light Lb. The second photosensitive polymer 1161 may include an organic material having light transmission.

The second scattering particles 1163 may scatter the blue light Lb that is not absorbed by the second quantum dots 1162 so as to excite more second quantum dots 1162, thereby increasing color conversion efficiency. The second scattering particles 1163 may include, for example, TiO₂, a metal particle, or the like. The second quantum dots 1162 may be selected from among a Group II-VI compound, a Group III-V compound, a Group IV-VI compound, a Group IV element, a Group IV compound, and a combination thereof.

In some embodiments, the first quantum dots 1152 may include the same material as the second quantum dots 1162. In this case, the size of each of the first quantum dots 1152 may be less than the size of each of the second quantum dots 1162.

While passing through the second color filter 30b, the color purity of the red light Lr converted by the second color conversion portion 40b may be improved. The second color filter 30b may include a pigment or dye of a second color (e.g., red).

The blue light Lb emitted from the third light-emitting diode LED3 of the light-emitting panel 1 may pass through the third color area of the color panel 2. The transmission portion 40c and the third color filter 30c provided in the third color area may be arranged to overlap the third light-emitting diode LED3. The blue light Lb emitted from the third light-emitting diode LED3 may pass through the transmission portion 40c, without color conversion, and then may be emitted to the outside by passing through the third color filter 30c.

The transmission portion 40c may transmit the blue light Lb without converting the blue light Lb incident on the transmission portion 40c. The transmission portion 40c may include, as illustrated in FIG. 3, a third photosensitive polymer 1171 in which third scattering particles 1173 are dispersed. The third photosensitive polymer 1171 may include, for example, an organic material having light transmission, such as silicon resin, epoxy resin, and the like, and may include the same material as the first and second photosensitive polymers 1151 and 1161. The third scattering particles 1173 may scatter and emit the blue light Lb and may include the same material as the first and second scattering particles 1153 and 1163.

The third color filter 30c may improve the color purity of the blue light Lb from the transmission portion 40c.

The first to third light-emitting diodes LED1, LED2, and LED3 may each include an organic light-emitting diode including an organic material. In another embodiment, the first to third light-emitting diodes LED1, LED2, and LED3 may each include an inorganic light-emitting diode including an inorganic material. The inorganic light-emitting diode may include a PN junction diode including materials based on an inorganic material semiconductor. When a voltage is applied to the PN junction diode in a forward direction, holes and electrons are injected and the energy generated by the recombination of the holes and the electrons is converted into light energy so that light of a certain color may be emitted. The inorganic light-emitting diode described above may have a width of several to hundreds of micrometers or several to hundreds of nanometers. In some embodiments, the light-emitting diode LED may be a light-emitting diode including quantum dots. As described above, an emission layer of the light-emitting diode LED may include an organic material, an inorganic material, quantum dots, an organic material and quantum dots, or an inorganic material and quantum dots.

The display device DV having the structure described above may include a mobile phone, a television, a billboard, a monitor, a tablet personal computer (PC), a notebook computer, and the like.

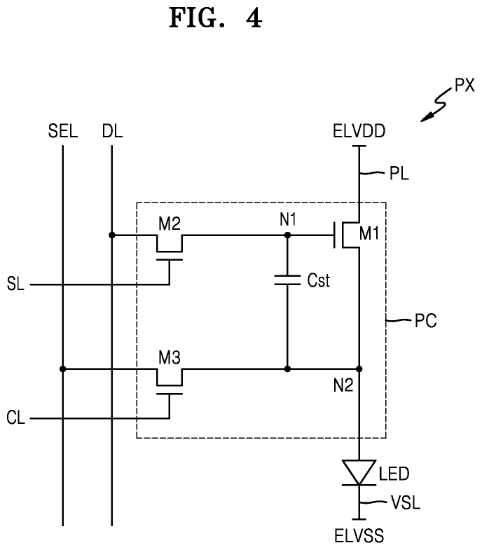

FIG. 4 is an equivalent circuit diagram of one pixel included in the display device DV according to an embodiment.

A pixel electrode (e.g., anode) of the light-emitting diode LED may be connected to a pixel circuit PC, and a counter electrode (e.g., cathode) of the light-emitting diode LED may be connected to a common voltage line VSL for providing a common power voltage ELVSS. The light-emitting diode LED may emit light with a luminance corresponding to the amount of current supplied from the pixel circuit PC.

The light-emitting diode LED of FIG. 4 may correspond to each of the first to third light-emitting diodes LED1, LED2, and LED3 described above with reference to FIG. 2, and the pixel circuit PC of FIG. 4 may correspond to each of the first to third pixel circuits PC1, PC2, and PC3 described above with reference to FIG. 2.

The pixel circuit PC may control, in response to a data signal, the amount of a current flowing from a driving voltage line PL to a common voltage line VSL via the light-emitting diode LED. The pixel circuit PC may include a driving transistor M1, a switching transistor M2, a sensing transistor M3, and a storage capacitor Cst.

Each of the driving transistor M1, the switching transistor M2, and the sensing transistor M3 may be an oxide semiconductor thin film transistor including a semiconductor layer formed of an oxide semiconductor, or a silicon semiconductor thin film transistor including a semiconductor layer formed of polysilicon. According to the type of a transistor, a first electrode may be one of a source electrode and a drain electrode, and a second electrode may be the other of the source electrode and the drain electrode.

The first electrode of the driving transistor M1 may be connected to the driving voltage line PL for providing the driving power voltage ELVDD, and the second electrode thereof may be connected to a first electrode of the light-emitting diode LED. A gate electrode of the driving transistor M1 may be connected to a first node N1. The driving transistor M1 may control, in response to a voltage of the first node N1, the amount of a current flowing from the driving voltage line PL to the light-emitting diode LED.

The switching transistor M2 may be a switching transistor. A first electrode of the switching transistor M2 may be connected to a data line DL, and a second electrode thereof may be connected to the first node N1. A gate electrode of the switching transistor M2 may be connected to a scan line SL. The switching transistor M2 may be turned on when a scan signal is supplied through the scan line SL to electrically connect the data line DL with the first node N1.

The sensing transistor M3 may be an initialization transistor and/or a sensing transistor. A first electrode of the sensing transistor M3 may be connected to a second node N2, and a second electrode thereof may be connected to a sensing line SEL. A gate electrode of the sensing transistor M3 may be connected to a control line CL.

The storage capacitor Cst may be connected between the first node N1 and the second node N2. For example, a first capacitor electrode of the storage capacitor Cst may be connected to the gate electrode of the driving transistor M1, and a second capacitor electrode of the storage capacitor Cst may be connected to the first electrode of the light-emitting diode LED.

In an embodiment, a method of driving the pixel circuit PC in an image display section is described as follows.

In a first section in which the switching transistor M2 receives an ON voltage of the scan line SL, the switching transistor M2 is turned on in response to the ON voltage of the scan signal. When the switching transistor M2 is turned on, a data voltage of the data line DL is applied to the gate electrode of the driving transistor M1 connected to the first node N1, and stored in the storage capacitor Cst.

The driving transistor M1 is turned on based on the data voltage, and due to the driving power voltage ELVDD, a driving current flows to the pixel electrode (e.g., anode) of the light-emitting diode LED. The light-emitting diode LED may display an image by emitting light by the driving current corresponding to the data voltage.

In a second section in which the sensing transistor M3 receives the ON voltage of the control line CL, the sensing transistor M3 is turned on in response to the on voltage of the control signal. The initialization voltage of the sensing line SEL is applied to the second node N2, for example, the first electrode of the light-emitting diode LED. Accordingly, the first electrode of the light-emitting diode LED may be initialized.

In the sensing section, a method of driving the pixel circuit PC is described as follows.

The switching transistor M2 is turned off in response to an off voltage of the scan signal, and the sensing transistor M3 is turned off in response to an off voltage of the control signal. Accordingly, a sensing signal applied to the second node N2 connected to the second electrode of the driving transistor M1 and the first electrode of the light-emitting diode LED may be provided to a control unit (or sensing unit) through the sensing line SEL. The control unit may generate sensing data that is digital data using the sensing signal and may compensate for and correct the image data using the sensing data.

Although FIG. 4 illustrates the driving transistor M1, the switching transistor M2, and the sensing transistor M3 as NMOS, the disclosure is not limited thereto. For example, at least one of the driving transistor M1, the switching transistor M2, and the sensing transistor M3 may be formed as PMOS.

Although FIG. 4 illustrates three transistors, the disclosure is not limited thereto. The pixel circuit PC may include four or more transistors.

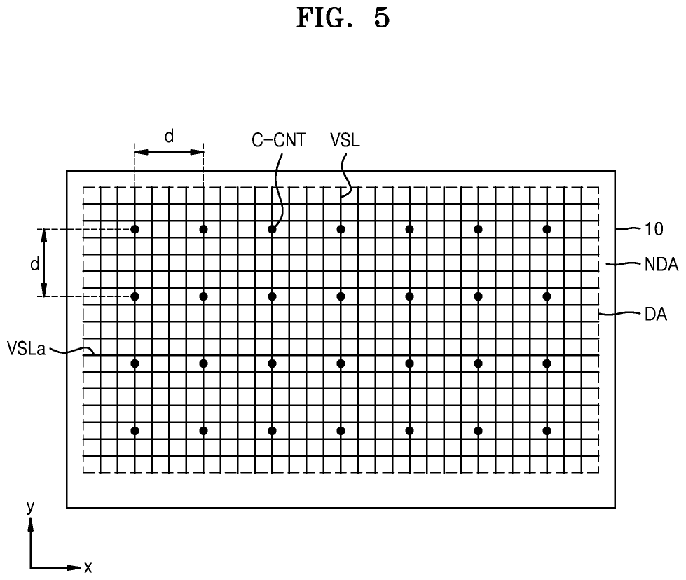

FIG. 5 is a plan view of common voltage lines VSL and auxiliary common voltage lines VSLa of the display device DV according to an embodiment.

Referring to FIG. 5, the display device DV may include the first substrate 10, and the first substrate 10 may include the display area DA and the non-display area NDA outside the display area DA. The display area DA may be an area for providing an image through an array of a plurality of pixels, and the non-display area NDA may be an area that does not provide an image.

The common voltage lines VSL and the auxiliary common voltage lines VSLa may be arranged in the display area DA. The common voltage lines VSL may extend in a first direction (e.g., y direction) and may be arranged apart from each other in a second direction (e.g., x direction) crossing the first direction (e.g., y direction). The auxiliary common voltage lines VSLa may extend in the second direction (e.g., x direction) and may be arranged apart from each other in the first direction (e.g., y direction).

Although not illustrated in FIG. 5, a main power line for providing the common power voltage ELVSS may be arranged in the non-display area NDA. The common voltage lines VSL may be electrically connected to the main power line.

The common voltage lines VSL and the auxiliary common voltage lines VSLa crossing each other may form a mesh structure, as illustrated in FIG. 5. The common voltage lines VSL and the auxiliary common voltage lines VSLa may be arranged on different layers. For example, at least one insulating layer may be arranged between the common voltage lines VSL and the auxiliary common voltage lines VSLa. The common voltage lines VSL and the auxiliary common voltage lines VSLa may be electrically connected to each other through contact holes defined in the at least one insulating layer between the common voltage lines VSL and the auxiliary common voltage lines VSLa. The contact holes connecting the common voltage lines VSL and the auxiliary common voltage lines VSLa may be located in the display area DA.

The cathode connectors C-CNT may be arranged to overlap the common voltage lines VSL. As the counter electrode (e.g., cathode) of the light-emitting diode LED described below and the common voltage line VSL are in direct contact with each other at the cathode connectors C-CNT, the common voltage line VSL and the counter electrode of the light-emitting diode LED may be electrically connected to each other.

When the counter electrode of the LED is too thick, the light emitted from the light-emitting diode LED does not transmit through the counter electrode and decreases. Accordingly, it may be advantageous to make the counter electrode thin. However, when the counter electrode is made thin, the resistance of the counter electrode increases, causing an undesirable luminance difference due to a voltage drop (IR-drop) in the display area DA. In the embodiments, as the counter electrode of the light-emitting diode LED is electrically connected to the common voltage line VSL through the cathode connector C-CNT, a voltage drop in the display area DA may be prevented or reduced.

As illustrated in FIG. 5, the cathode connectors C-CNT may be arranged a certain distance apart from each other. For example, the cathode connectors C-CNT neighboring each other may be apart from each other by a first distance d. In an embodiment, the first distance d may be about 3 cm to about 5 cm. The cathode connectors C-CNT overlap some of the common voltage lines VSL, and one or more common voltage lines VSL that do not overlap the cathode connector C-CNT may be arranged between the cathode connectors C-CNT. Although the first distance d is shown to be the distance between two cathode connectors C-CNT that are connected to the same common voltage line VSL, the first distance d may also apply to cathode connectors C-CNT that are on different common voltage lines VSL.

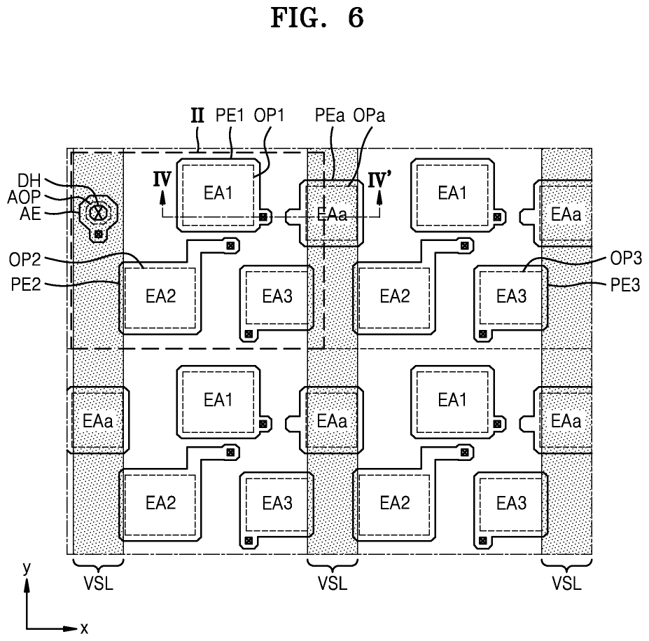

FIG. 6 is a schematic layout diagram of an arrangement of the common voltage lines VSL and pixel electrodes of the display device DV according to an embodiment.

Referring to FIG. 6, the display device DV may include the common voltage lines VSL extending in the first direction (e.g., y direction). A first pixel electrode PE1, a second pixel electrode PE2, and a third pixel electrode PE3 may be arranged in an area between the common voltage lines VSL neighboring each other. A pixel defining layer is disposed on the first pixel electrode PE1, the second pixel electrode PE2, and the third pixel electrode PE3, and a first pixel opening OP1 overlapping the first pixel electrode PE1, a second pixel opening OP2 overlapping the second pixel electrode PE2, and a third pixel opening OP3 overlapping the third pixel electrode PE3 may be defined in the pixel defining layer.

The first pixel electrode PE1 may be the pixel electrode (e.g., anode) of the first light-emitting diode LED1, the second pixel electrode PE2 may be a first electrode of the second light-emitting diode LED2, and the third pixel electrode PE3 may be a first electrode of the third light-emitting diode LED3.

An emission layer may be arranged within the first pixel opening OP1, the second pixel opening OP2, and the third pixel opening OP3, and the first pixel opening OP1, the second pixel opening OP2, and the third pixel opening OP3 may correspond to a first emission area EA1, a second emission area EA2, and a third emission area EA3, respectively.

An auxiliary electrode AE and preliminary electrodes PEa may be arranged to overlap the common voltage lines VSL. An auxiliary opening AOP overlapping the auxiliary electrode AE and preliminary openings OPa overlapping the preliminary electrodes PEa may be defined in the pixel defining layer.

The preliminary electrode PEa may be a first electrode of a preliminary light-emitting diode. An emission layer may be arranged within the preliminary opening OPa, and the preliminary opening OPa may correspond to a preliminary emission area EAa. In an embodiment, the size of the first pixel electrode PE1 may be greater than the size of the preliminary electrode PEa. The size of the first emission area EA1 may be greater than the size of the preliminary emission area EAa. The size of the preliminary electrode PEa may be greater than the size of the auxiliary electrode AE.

A through-hole may be formed in the auxiliary opening AOP by removing part of an intermediate layer that is disposed in the auxiliary opening AOP. The through-hole may be a drilling hole DH formed in a laser drilling process. The auxiliary electrode AE may be arranged on the common voltage line VSL and may be electrically connected to the common voltage line VSL that overlaps auxiliary electrode AE.

The counter electrode of the light-emitting diode LED is in contact with the auxiliary electrode AE via the drilling hole DH and the auxiliary opening AOP, and thus, the cathode connector C-CNT described with reference to FIG. 5 may be formed. The cathode connector C-CNT may include a plurality of cathode connectors arranged apart a certain distance from each other in the display area DA, and thus, the auxiliary electrode AE may also include a plurality of auxiliary electrodes. The auxiliary electrodes AE may be arranged two-dimensionally on an x-y plane forming an array, and one or more preliminary electrodes PEa may be arranged between two auxiliary electrodes AE neighboring in the first direction (e.g., y direction) or the second direction (e.g., x direction). In other words, a virtual straight line connecting the centers of the two auxiliary electrodes AE neighboring in the first direction (e.g., y direction) or the second direction (e.g., x direction) may intersect one or more preliminary electrodes PEa.

Although the preliminary electrode PEa is disposed on the common voltage line VSL, the preliminary electrode PEa may not be electrically connected to the common voltage line VSL that overlaps the preliminary electrode PEa. The preliminary electrode PEa may be in a floating state of not being electrically connected to other elements under the preliminary electrode PEa.

The preliminary electrode PEa may be arranged adjacent to the first pixel electrode PE1. For example, as illustrated in FIG. 6, the preliminary electrode PEa may be arranged between the first pixel electrodes PE1 of the two neighboring pixel areas.

The first pixel electrode PE1 may correspond to a first electrode of the first light-emitting diode LED1 for implementing the green pixel Pg described with reference to FIG. 2. As the green pixel Pg has high visibility, when a dark spot defect occurs in the first light-emitting diode LED1 in a manufacturing process, the quality of an image displayed by the display device DV may be much deteriorated. In this case, a defective pixel may be replaced by electrically connecting the preliminary electrode PEa in a floating state to the first pixel circuit PC1 or a preliminary pixel circuit. Accordingly, the process yield of the display device DV may be improved. Furthermore, by arranging the preliminary electrodes PEa in an area overlapping the common voltage line VSL, wasted area may be utilized without consumption of an additional area.

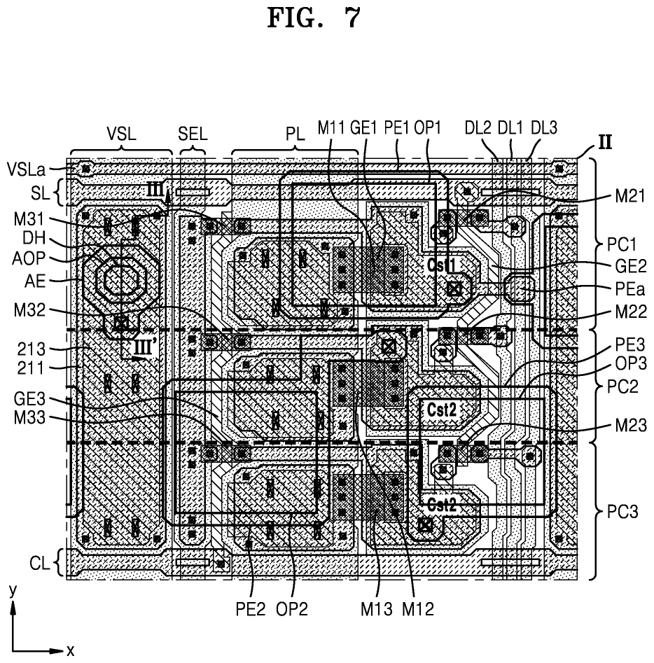

FIG. 7 is a schematic layout diagram of the display device DV according to an embodiment.

Referring to FIG. 7, the sensing line SEL, the driving voltage line PL, the first to third data lines DL1, DL2, and DL3, and the common voltage line VSL may be disposed on the light-emitting panel 1. The sensing line SEL, the driving voltage line PL, the first to third data lines DL1, DL2, and DL3, and the common voltage line VSL may extend in the first direction (e.g., y direction).

The auxiliary common voltage line VSLa, the scan line SL, and the control line CL may extend in the second direction (e.g., x direction) crossing the first direction (e.g., y direction).

The two common voltage lines VSL neighboring each other are arranged spaced apart from each other, and the first to third data lines DL1, DL2, and DL3, the sensing line SEL, and the driving voltage line PL may be arranged between the two common voltage lines VSL neighboring each other as described above. The sensing line SEL and the driving voltage line PL, while neighboring each other, may be arranged adjacent to any one common voltage line VSL. The first to third data lines DL1, DL2, and DL3, while neighboring one another, may be arranged adjacent to another common voltage line VSL. For example, with respect to the first to third storage capacitors Cst1, Cst2, and Cst3 described below, the sensing line SEL and the driving voltage line PL may be arranged on one side (e.g., the left side), and the first to third data lines DL1, DL2, and DL3 may be arranged on the other side (e.g., the right side). The space of the light-emitting panel 1 may be efficiently used through the above structure.

The auxiliary common voltage line VSLa may extend in the second direction (e.g., x direction) to cross the common voltage line VSL. The auxiliary common voltage line VSLa may be arranged between the scan line SL and the control line CL. The auxiliary common voltage line VSLa may be electrically connected to the common voltage lines VSL.

The light-emitting panel 1 may have a structure in which the structure illustrated in FIG. 7 is repeated in the first direction (e.g., y direction) and the second direction (e.g., x direction). Accordingly, the common voltage line VSL and the auxiliary common voltage line VSLa provided in the light-emitting panel 1 may form a mesh structure on a plane.

The first to third pixel circuits PC1, PC2, and PC3 may be arranged in an approximately rectangular space surrounded, on a plane, by the two common voltage lines VSL neighboring each other and the two auxiliary common voltage lines VSLa neighboring each other. The approximately rectangular space in which the first to third pixel circuits PC1, PC2, and PC3 described above are arranged may be defined as a unit area.

The first to third pixel circuits PC1, PC2, and PC3 may be electrically connected to the pixel electrode (e.g., anode) of a corresponding light-emitting diode LED. In this connection, FIG. 7 illustrates that the first pixel electrode PE1, the second pixel electrode PE2, and the third pixel electrode PE3 are electrically connected to the first pixel circuit PC1, the second pixel circuit PC2, and the third pixel circuit PC3, respectively.

The first pixel electrode PE1 may be electrically connected to the first pixel circuit PC1, and the first pixel circuit PC1 may include, as illustrated in FIG. 7, a first driving transistor M11, a first switching transistor M21, a first sensing transistor M31, and a first storage capacitor Cst1.

The second pixel electrode PE2 may be electrically connected to the second pixel circuit PC2, and the second pixel circuit PC2 may include a second driving transistor M12, a second switching transistor M22, a second sensing transistor M32, and a second storage capacitor Cst2.

The third pixel electrode PE3 may be electrically connected to the third pixel circuit PC3, and the third pixel circuit PC3 may include a third driving transistor M13, a third switching transistor M23, a third sensing transistor M33, and a third storage capacitor Cst3.

The first to third storage capacitors Cst1, Cst2, and Cst3 may be arranged in the first direction (e.g., y direction). The first storage capacitor Cst1 may be arranged close to the scan line SL, and the third storage capacitor Cst3 may be arranged close to the control line CL.

The first driving transistor M11 may include a first driving semiconductor layer and a driving gate electrode GE1. The first driving semiconductor layer may include an oxide semiconductor or a silicon-based semiconductor. The driving gate electrode GE1 may be arranged to overlap a channel region of the first driving semiconductor layer. One side of the first driving semiconductor layer may be electrically connected to the driving voltage line PL, and the other side of the first driving semiconductor layer may be electrically connected to a first capacitor electrode CE1 of the first storage capacitor Cst1.

The first switching transistor M21 may include a first switching semiconductor layer and a switching gate electrode GE2. The first switching semiconductor layer may include an oxide semiconductor or a silicon-based semiconductor. The switching gate electrode GE2 may be arranged to overlap a channel region of the first switching semiconductor layer. The switching gate electrode GE2 may extend in the direction (e.g., y direction) crossing the scan line SL, and may be electrically connected to the scan line SL.

The switching gate electrode GE2 may correspond to a gate electrode of each of the first switching transistor M21, the second switching transistor M22, and the third switching transistor M23. The switching gate electrode GE2 may extend between a group of the first to third storage capacitors Cst1, Cst2, and Cst3 and a group of the first to third data lines DL1, DL2, and DL3, to overlap with the first switching semiconductor layer, the second switching semiconductor layer, and the third switching semiconductor layer.

One side of the first switching semiconductor layer may be electrically connected to a second capacitor electrode CE2 of the first storage capacitor Cst1, and the other side of the first switching semiconductor layer may be electrically connected to the first data line DL1 through a connection electrode.

The third driving transistor M13 may include a first sensing semiconductor layer and a sensing gate electrode GE3. The first sensing semiconductor layer may include an oxide semiconductor or a silicon-based semiconductor. The sensing gate electrode GE3 may overlap a channel region of the first sensing semiconductor layer. The sensing gate electrode GE3 may extend in the direction (e.g., y direction) crossing the control line CL and may be electrically connected to the control line CL.

The sensing gate electrode GE3 may correspond to a gate electrode of each of the first sensing transistor M31, the second sensing transistor M32, and the third sensing transistor M33. The sensing gate electrode GE3 may extend between the sensing line SEL and the driving voltage line PL to overlap with the first sensing semiconductor layer, the second sensing semiconductor layer, and the third sensing semiconductor layer.

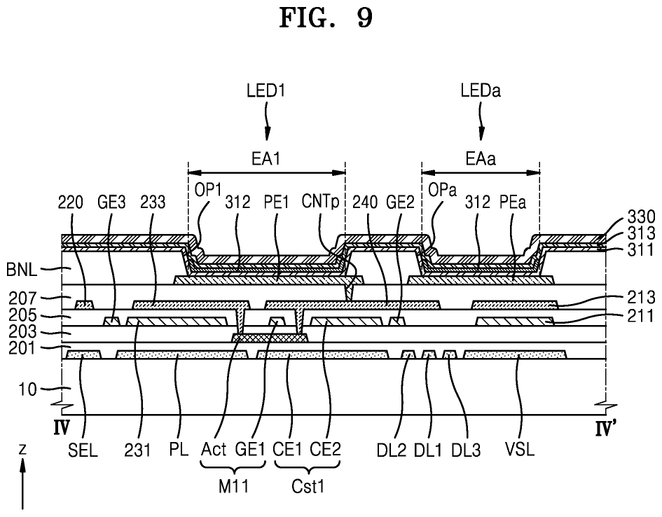

One side of the first sensing semiconductor layer may be electrically connected to the sensing line SEL through an auxiliary sensing line 220 (see FIG. 9) on the sensing line SEL, and the other side of the first sensing semiconductor layer may be electrically connected to the first capacitor electrode CE1 of the first storage capacitor Cst1. The auxiliary sensing line 220 may extend in the direction (e.g., y direction) in which the sensing line SEL extends to overlap with the sensing line SEL. The auxiliary sensing line 220 may be arranged, on a plane, between the scan line SL and the control line CL and may have a length less than a separation distance between the scan line SL and the control line CL (separation distance in the y direction).

The first storage capacitor Cst1 may include at least two electrodes. In an embodiment, the first storage capacitor Cst1 may include the first capacitor electrode CE1 and the second capacitor electrode CE2. A third connection member 240 (see FIG. 9) disposed on the second capacitor electrode CE2 to overlap with the first capacitor electrode CE1 and the second capacitor electrode CE2 may function as a sub-electrode of the first storage capacitor Cst1. The third connection member 240 may be electrically connected to the first capacitor electrode CE1.

The specific structures and materials of the second driving transistor M12 and the third driving transistor M13 may be the same as or similar to those of the first driving transistor M11 described above. The structures and materials of the second switching transistor M22 and the third switching transistor M23 may be the same as or similar to those of the second driving transistor M12 described above, except for respectively being connected to the second data line DL2 and the third data line DL3. The specific structures and materials of the second sensing transistor M32 and the third sensing transistor M33 may be the same as or similar to those of the third driving transistor M13 described above.

The first light-emitting diode LED1 may be electrically connected to the first pixel circuit PC1. Likewise, the second light-emitting diode LED2 may be electrically connected to the second pixel circuit PC2, and the third light-emitting diode LED3 may be electrically connected to the third pixel circuit PC3.

The first pixel electrode PE1, the second pixel electrode PE2, and the third pixel electrode PE3 may be arranged in the unit area in which the first to third pixel circuits PC1, PC2, and PC3 are arranged. For example, the first pixel electrode PE1 may be arranged to overlap the first pixel circuit PC1, and the second pixel electrode PE2 and the third pixel electrode PE3 may be arranged to respectively overlap the second pixel circuit PC2 and the third pixel circuit PC3. A pixel defining layer may be disposed on the first to third pixel electrodes PE1, PE2, and PE3, and the first pixel opening OP1 for exposing a part of the first pixel electrode PE1, the second pixel opening OP2 for exposing a part of the second pixel electrode PE2, and the third pixel opening OP3 for exposing a part of the third pixel electrode PE3 may be defined in the pixel defining layer.

A first auxiliary voltage line 211 and a second auxiliary voltage line 213 may be disposed on the common voltage line VSL. The first auxiliary voltage line 211 and the second auxiliary voltage line 213 may extend in the direction (y direction) in which the common voltage line VSL extends to overlap with the common voltage line VSL.

The first auxiliary voltage line 211 and the second auxiliary voltage line 213 may be arranged, on a plane, between the scan line SL and the control line CL, and may each have a length less than the separation distance between the scan line SL and the control line CL (separation distance in the y direction).

The auxiliary electrode AE or the preliminary electrode PEa may be arranged to overlap the common voltage line VSL, the first auxiliary voltage line 211, and the second auxiliary voltage line 213. The auxiliary electrode AE and the preliminary electrode PEa may be arranged adjacent to the first pixel circuit PC1.

The auxiliary electrode AE may be electrically connected to the common voltage line VSL through the first auxiliary voltage line 211 and the second auxiliary voltage line 213. In contrast, the preliminary electrode PEa having no contact portion may be a floating state of not being electrically connected to the lines, connection electrodes, and connection members thereunder.

The auxiliary opening AOP for exposing a part of the auxiliary electrode AE and the preliminary opening OPa for exposing a part of the preliminary electrode PEa may be defined in the pixel defining layer on the auxiliary electrode AE and the preliminary electrode PEa. The drilling hole DH defined in the intermediate layer may overlap the auxiliary opening AOP. For example, the drilling hole DH may be located at about the center of the auxiliary opening AOP.

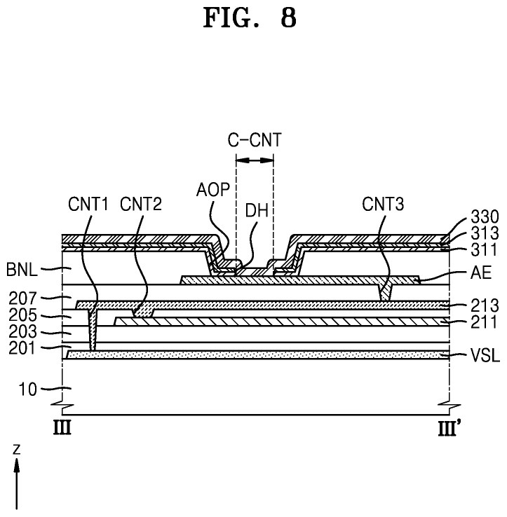

FIG. 8 is a schematic cross-sectional view of the display device DV of FIG. 7 taken along line III-III′.

Referring to FIG. 8, the light-emitting panel 1 may include the first substrate 10.

The first substrate 10 may include a glass material or a resin material. The glass material may include transparent glass containing silicon oxide as a main ingredient. The resin material may include polymer resin, such as polyethersulfone, polyacrylate, polyetherimide, polyethylene naphthalate, polyethylene terephthalate, polyphenylene sulfide, polyarylate, polyimide, polycarbonate, cellulose triacetate, cellulose acetate propionate, and the like. When the first substrate 10 includes the polymer resin described above, the display device DV may be flexible, rollable, or bendable.

The common voltage line VSL is disposed on the first substrate 10, and the common voltage line VSL may include metal, such as molybdenum (Mo), copper (Cu), or titanium (Ti). The common voltage line VSL may be disposed directly above the first substrate 10 and may be in direct contact with the first substrate 10. Alternatively, an insulating layer may be arranged between the common voltage line VSL and the first substrate 10.

A first insulating layer (buffer layer) 201 may be disposed on the common voltage line VSL, and a second insulating layer (gate insulating layer) 203 may be disposed on the first insulating layer 201. A semiconductor layer may be arranged between the first insulating layer 201 and the second insulating layer 203. The first insulating layer 201 may prevent impurities from infiltrating into the semiconductor layer. The first insulating layer 201 may include an inorganic insulating material, such as a silicon nitride, a silicon oxide, and/or a silicon oxynitride.

The second insulating layer 203 may include an inorganic insulating material, such as a silicon nitride, a silicon oxide, and/or a silicon oxynitride, or an organic insulating material. The second insulating layer 203 may have a single layer or multilayer structure including the material described above.

The first auxiliary voltage line 211 may be disposed on the second insulating layer 203. The first auxiliary voltage line 211 may include Mo, Cu, Ti, and the like and may have a single layer or multilayer structure including the material described above.

A third insulating layer (first interlayer insulating layer) 205 may be disposed on the first auxiliary voltage line 211. The third insulating layer 205 may include an inorganic insulating material, such as a silicon nitride, a silicon oxide, and/or a silicon oxynitride, or an organic insulating material.

The second auxiliary voltage line 213 may be disposed on the third insulating layer 205 and may be electrically connected to the common voltage line VSL through a first contact portion CNT1 penetrating the third insulating layer 205, the second insulating layer 203, and the first insulating layer 201, and to the first auxiliary voltage line 211 through a second contact portion CNT2 penetrating the third insulating layer 205. The second auxiliary voltage line 213 may include Mo, Cu, Ti, and the like and may have a single layer or multilayer structure including the material described above.

The first auxiliary voltage line 211 and the second auxiliary voltage line 213 may be disposed on a different layer from the common voltage line VSL and electrically connected to each other, thereby preventing a local voltage drop according to the resistance of the common voltage line VSL.

A fourth insulating layer (second interlayer insulating layer) 207 may be disposed on the second auxiliary voltage line 213. The fourth insulating layer 207 may include an organic insulating material and/or an inorganic insulating material. The organic insulating material may include, for example, a general purpose polymer, such as, polymethylmethacrylate (PMMA) or polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, or blends thereof, and the like.

The auxiliary electrode AE may be disposed on the fourth insulating layer 207. The auxiliary electrode AE may be electrically connected to the second auxiliary voltage line 213 through a third contact portion CNT3 penetrating the fourth insulating layer 207. The auxiliary electrode AE may include a transparent conductive oxide, such as an indium tin oxide (ITO), an indium zinc oxide (IZO), a zinc oxide (ZnO), an indium oxide (In₂O₃), an indium gallium oxide (IGO), or an aluminum zinc oxide (AZO). In another embodiment, the auxiliary electrode AE may include a reflective film including magnesium (Mg), silver (Ag), aluminum (Al), platinum (Pt), palladium (Pd), gold (Au), nickel (Ni), neodymium (Nd), iridium (Ir), chromium (Cr) or a compound thereof. In another embodiment, the auxiliary electrode AE may further include a film formed of ITO, IZO, ZnO or In₂O₃ above/below the reflective film described above. The auxiliary electrode AE may have a three layer structure of an ITO layer, an Ag layer, and an ITO layer. Although FIG. 8 illustrates the auxiliary electrode AE, the first pixel electrode PE1, the second pixel electrode PE2, the third pixel electrode PE3, and the preliminary electrode PEa illustrated in FIG. 7 may be disposed on the same layer as the auxiliary electrode AE and may include the same material.

To cover a part of the auxiliary electrode AE, a pixel defining layer BNL may be disposed on the fourth insulating layer 207. The auxiliary opening AOP for exposing a part of the auxiliary electrode AE may be defined in the pixel defining layer BNL.

An intermediate layer and a counter electrode 330 (e.g., cathode) may be disposed on the pixel defining layer BNL. The intermediate layer may be provided between the auxiliary electrode AE and the counter electrode 330 and may be integrally formed to entirely cover the display area DA. The intermediate layer may include a first function layer 311 disposed below an emission layer described below and a second function layer 313 disposed above the emission layer. The emission layer may not be disposed on the auxiliary electrode AE. In other words, the auxiliary electrode AE may not overlap with the emission layer.

The drilling hole DH for exposing a part of the auxiliary electrode AE may be defined in the first function layer 311 and the second function layer 313. The drilling hole DH may be arranged to overlap the auxiliary opening AOP. The drilling hole DH may be located at about the center of the auxiliary opening AOP.

The counter electrode 330 may be a semi-transmissive or transmissive electrode. The counter electrode 330 may be a semi-transmissive electrode including an ultra-thin film metal including Mg, Ag, Al, Pt, Pd, Au, Ni, Nd, Ir, Cr, or a compound thereof. The counter electrode 330 may include a transparent conductive oxide, such as ITO, an indium zinc oxide (IZO), a zinc oxide (ZnO), an indium oxide (In₂O₃), an indium gallium oxide (IGO), or an aluminum zinc oxide (AZO).

The counter electrode 330 may be in direct contact with a part of the auxiliary electrode AE exposed by the auxiliary opening AOP and the drilling hole DH, thereby forming the cathode connector C-CNT. As described above, as the auxiliary electrode AE is electrically connected to the common voltage line VSL through the second auxiliary voltage line 213 and the first auxiliary voltage line 211, a voltage drop according to the resistance of the counter electrode 330 may be prevented or reduced.

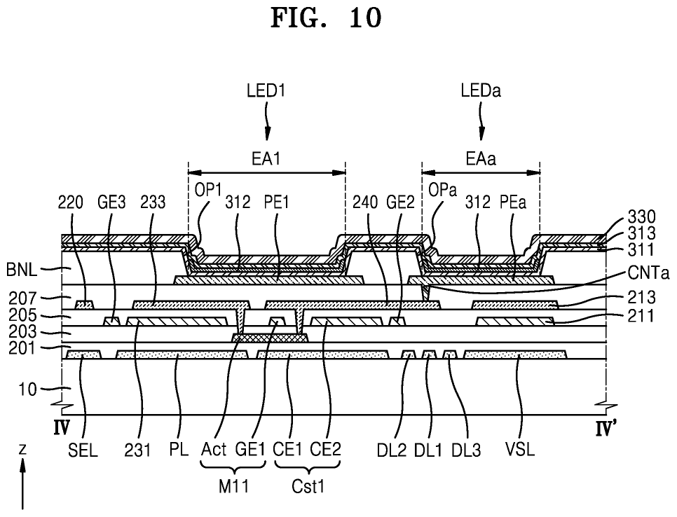

FIGS. 9 and 10 are schematic cross-sectional views of the display device DV of FIG. 6 taken along line IV-IV′.

Referring to FIGS. 9 and 10, the light-emitting panel 1 may include the first substrate 10, and the sensing line SEL, the driving voltage line PL, the first capacitor electrode CE1 of the first storage capacitor Cst1, the first to third data lines DL1, DL2, and DL3, and the common voltage line VSL may be disposed on the first substrate 10 apart from each other in the second direction (e.g., x direction). The sensing line SEL, the driving voltage line PL, the first capacitor electrode CE1 of the first storage capacitor Cst1, and the first to third data lines DL1, DL2, and DL3, may include the same material as the common voltage line VSL. For example, the sensing line SEL, the driving voltage line PL, the first capacitor electrode CE1 of the first storage capacitor Cst1, and the first to third data lines DL1, DL2, and DL3 may include a metal such as, Mo, Cu, and Ti.

The first insulating layer 201 may be disposed on the sensing line SEL, the driving voltage line PL, the first capacitor electrode CE1 of the first storage capacitor Cst1, the first to third data lines DL1, DL2, and DL3, and the common voltage line VSL, and a semiconductor layer Act may be disposed on the first insulating layer 201. The semiconductor layer Act disclosed in FIG. 9 may correspond to a first driving semiconductor layer included in the first driving transistor M11. The semiconductor layer Act may include an oxide semiconductor or a silicon-based semiconductor.

The second insulating layer 203 may be disposed on the first insulating layer 201 to cover the semiconductor layer Act. The sensing gate electrode GE3, a first connection member 231, the driving gate electrode GE1, the switching gate electrode GE2, and the first auxiliary voltage line 211 may be disposed on the second insulating layer 203 apart from each other in the second direction (e.g., x direction). The sensing gate electrode GE3, the first connection member 231, the driving gate electrode GE1, and the switching gate electrode GE2 may include the same material as the first auxiliary voltage line 211. For example, the sensing gate electrode GE3, the first connection member 231, the driving gate electrode GE1, and the switching gate electrode GE2 may include metal such as, Mo, Cu, and Ti.

The first connection member 231 may extend in the direction (e.g., y direction) in which the driving voltage line PL extends, to overlap the driving voltage line PL. The first connection member 231 may be electrically connected to the driving voltage line PL through a second connection member 233 described below, and a local voltage drop according to the resistance of the driving voltage line PL may be prevented.

The driving gate electrode GE1 may be arranged to overlap the semiconductor layer Act, and the driving gate electrode GE1 and the semiconductor layer Act may constitute the first driving transistor M11. The driving gate electrode GE1 may be formed integrally with the second capacitor electrode CE2 of the storage capacitor Cst.

The first capacitor electrode CE1 and the second capacitor electrode CE2 may be arranged to overlap each other, and may constitute the first storage capacitor Cst1. The first capacitor electrode CE1 may be electrically connected to the first pixel electrode PE1 through the third connection member 240 described below. The second capacitor electrode CE2 may be electrically connected to the first data line DL1 via the first switching transistor M21.

The switching gate electrode GE2 may extend in the first direction (e.g., y direction) to overlap the first switching semiconductor layer, the second switching semiconductor layer, and the third switching semiconductor layer. The sensing gate electrode GE3 may extend in the first direction (e.g., y direction) to overlap the first sensing semiconductor layer, the second sensing semiconductor layer, and the third sensing semiconductor layer.

The third insulating layer 205 may be disposed on the second insulating layer 203 to cover the sensing gate electrode GE3, the first connection member 231, the driving gate electrode GE1, the switching gate electrode GE2, and the first auxiliary voltage line 211. The auxiliary sensing line 220, the second connection member 233, the third connection member 240, and the second auxiliary voltage line 213 may be disposed on the third insulating layer 205 apart from each other in the second direction (e.g., x direction). The auxiliary sensing line 220, the second connection member 233 and the third connection member 240 may include the same material as the second auxiliary voltage line 213. For example, the auxiliary sensing line 220, the second connection member 233, and the third connection member 240 may include metal such as, Mo, Cu, and Ti.

The auxiliary sensing line 220 may extend in the direction (e.g., y direction) in which the sensing line SEL extends, to overlap the sensing line SEL. The auxiliary sensing line 220 may electrically connect the sensing line SEL to first sensing semiconductor layer. The auxiliary sensing line 220 and the sensing line SEL may be disposed on different layers and electrically connected to each other, so that a local voltage drop according to the resistance of the sensing line SEL may be prevented.

The second connection member 233 may be arranged to overlap the driving voltage line PL and the first connection member 231, and may extend in the direction (e.g., y direction) in which the driving voltage line PL extends. The second connection member 233 may be electrically connected to the first connection member 231 and the driving voltage line PL. The first connection member 231, the second connection member 233, and the driving voltage line PL may be disposed on different layers and electrically connected to one another, so that a local voltage drop according to the resistance of the driving voltage line PL may be prevented. The second connection member 233 may be electrically connected to one side of the semiconductor layer Act through a contact hole defined in the third insulating layer 205 and the second insulating layer 203.

The third connection member 240 may be arranged to overlap the first capacitor electrode CE1 and the second capacitor electrode CE2. As the third connection member 240 is electrically connected to the first capacitor electrode CE1, the third connection member 240 may function as the sub-electrode of the first storage capacitor Cst1.

The third connection member 240 may be electrically connected to the one side of the semiconductor layer Act through the contact hole defined in the third insulating layer 205 and the second insulating layer 203. A through-hole may be defined between the second capacitor electrode CE2 and the driving gate electrode GE1 provided as one body so that the third connection member 240 may contact the one side of the semiconductor layer Act.

The fourth insulating layer 207 may be disposed on the third insulating layer 205 to cover the auxiliary sensing line 220, the second connection member 233, the third connection member 240, and the second auxiliary voltage line 213. The first pixel electrode PE1 and the preliminary electrode PEa may be disposed on the fourth insulating layer 207 apart from each other. As described above, the first pixel electrode PE1 and the preliminary electrode PEa may include the same material as the auxiliary electrode AE.

The first pixel electrode PE1 may be arranged to overlap the first driving transistor M11. The first pixel electrode PE1 may be electrically connected to the third connection member 240 through a pixel contact portion CNTp extending through the fourth insulating layer 207.

The preliminary electrode PEa may be arranged to overlap the common voltage line VSL, the first auxiliary voltage line 211, and the second auxiliary voltage line 213. The preliminary electrode PEa may be formed in a floating state of not being electrically connected to the lines, transistors, and storage capacitor and the like thereunder.

The pixel defining layer BNL may be disposed on the fourth insulating layer 207 to cover a part of the first pixel electrode PE1 and a part of the preliminary electrode PEa. The pixel defining layer BNL may cover an edge of the first pixel electrode PE1, and define the first pixel opening OP1 for exposing the center of the first pixel electrode PE1. The pixel defining layer BNL may cover an edge of the preliminary electrode PEa, and define the preliminary opening OPa for exposing the center of the preliminary electrode PEa. The first emission area EA1 of the first light-emitting diode LED1 may be defined by the first pixel opening OP1, and the preliminary emission area EAa of a preliminary light-emitting diode LEDa may be defined by the preliminary opening OPa.

The pixel defining layer BNL may include an organic insulating material, such as benzocyclobutene (BCB), polyimide, hexamethyldisiloxane (HMDSO), or the like. The pixel defining layer BNL may be formed in black. The pixel defining layer BNL may include a light shielding material, and may be provided in black. The light shielding material may include carbon black, carbon nanotube, resin or paste including black dye, a metal particle, for example, N, Al, Mo, and an alloy thereof , a metal oxide particle (e.g., chromium oxide), a metal nitride particle (e.g., chromium nitride), or the like.

An intermediate layer may be disposed on the pixel defining layer BNL. The intermediate layer may include the first function layer 311, the second function layer 313, and an emission layer 312. The first function layer 311 and the second function layer 313 may be integrally provided to cover the entire surface of the display area DA. The emission layers 312 may be arranged between first function layer 311 and the second function layer 313. Unlike that the first function layer 311 and the second function layer 313 that may be integrally provided, the emission layer 312 may be arranged to be patterned to correspond to each of the first pixel electrode PE1 and the preliminary electrode PEa. As described above, the auxiliary electrode AE may not overlap with the emission layer 312.

The emission layer 312 may include a polymer organic material or a low molecular weight organic material, which emits light of a certain color. In an embodiment, the emission layer 312 arranged to correspond to the first pixel electrode PE1 and the emission layer 312 arranged to correspond to the preliminary electrode PEa may emit light of the same color.

The first function layer 311 may be arranged between the emission layer 312 and the first pixel electrode PE1 and between the emission layer 312 and the preliminary electrode PEa. The first function layer 311 may have a single layer or multilayer structure. For example, the first function layer 311 may include, as a hole transport layer (HTL), poly-(3,4)-ethylene-dihydroxy thiophene (PEDOT) or polyaniline (PANI). Alternatively, the first function layer 311 may include a hole injection layer (HIL) and a hole transport layer (HTL).

The second function layer 313 may be arranged between the emission layers 312 and the counter electrode 330. The second function layer 313 may include an electron transport layer (ETL) and/or an electron injection layer (EIL). In some embodiments, at least one of HIL, HTL, ETL, and EIL may be omitted.

The first pixel electrode PE1, the counter electrode 330, and the intermediate layer provided between the first pixel electrode PE1 and the counter electrode 330 may constitute the first light-emitting diode LED1. The preliminary electrode PEa, the counter electrode 330, and the intermediate layer provided between the preliminary electrode PEa and the counter electrode 330 may constitute the preliminary light-emitting diode LEDa.

When the first light-emitting diode LED1 functions normally, the preliminary light-emitting diode LEDa may not be electrically connected to the pixel circuit PC. In other words, as illustrated in FIG. 9, the preliminary electrode PEa of the preliminary light-emitting diode LEDa may be in a floating state of not being electrically connected to the constituent elements thereunder. Accordingly, the preliminary light-emitting diode LEDa may not emit light.

In contrast, when the first light-emitting diode LED1 functions abnormally, the preliminary light-emitting diode LEDa may be electrically connected to the pixel circuit PC. In other words, as illustrated in FIG. 10, the pixel contact portion CNTp electrically connecting the first pixel electrode PE1 to the third connection member 240 is removed, and a preliminary contact portion CNTa electrically connecting the preliminary electrode PEa to the third connection member 240 may be formed. In an embodiment, the removal of the pixel contact portion CNTp and the formation of the preliminary contact portion CNTa may be performed using a laser irradiation process.

Although FIG. 10 illustrates a case in which the preliminary light-emitting diode LEDa electrically connected to the first pixel circuit PC1, in another embodiment, the preliminary light-emitting diode LEDa may be electrically connected to a separate preliminary pixel circuit.

As green light has high visibility, when a dark spot defect occurs in the first light-emitting diode LED1 forming a green pixel, the quality of an image displayed by a display device may be much deteriorated. According to some embodiments, by electrically connecting the preliminary light-emitting diodes LEDa prepared in a floating state to the first pixel circuit PC1 or the preliminary pixel circuit, a defective pixel may be replaced. Accordingly, the process yield of a display device may be improved.

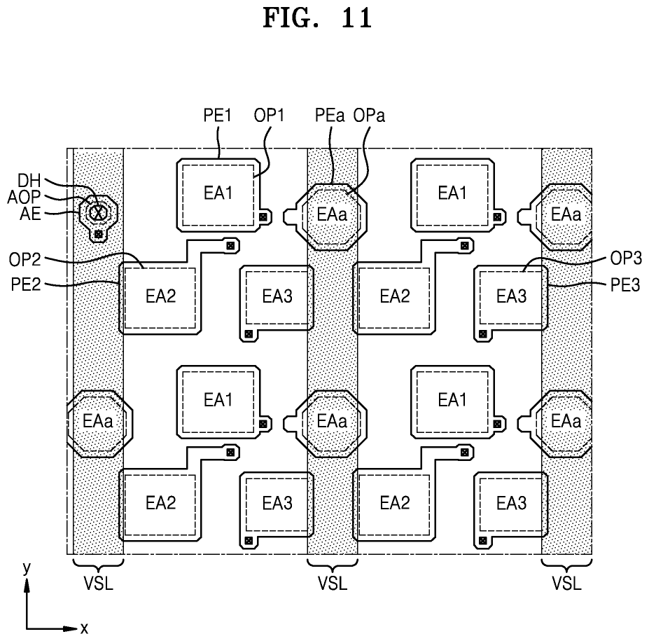

FIG. 11 is a schematic layout diagram of an arrangement of the common voltage line VSL and the pixel electrode of the display device DV according to an embodiment. FIG. 11 is similar to FIG. 6, but has a difference in the shape of the preliminary electrode PEa. The descriptions of the same constituent elements are omitted, and differences are mainly described.

Referring to FIG. 11, the preliminary electrode PEa may have a shape similar to the auxiliary electrode AE. For example, the preliminary electrode PEa may have an octagonal shape like the auxiliary electrode AE. However, the disclosure is not limited thereto, and the preliminary electrode PEa may have various shapes, such as a circle, an oval, a polygon, and the like.

Although FIG. 11 illustrates that the area of the preliminary electrode PEa is greater than the area of the auxiliary electrode AE, in another embodiment, the area of the preliminary electrode Pea may be the same as the area of the auxiliary electrode AE. Although the area of the preliminary electrode PEa may be less than the area the first pixel electrode PE1, in another embodiment, the area of the preliminary electrode PEa may be equal to or greater than the size of the first pixel electrode PE1.

Virtual straight lines passing through the center of the auxiliary electrode AE and extending the first direction (e.g., y direction) and in the second direction (e.g., x direction) may intersect the preliminary electrodes PEa. The preliminary electrodes PEa may be located at a position corresponding to the auxiliary opening AOP with respect to each unit area.

As the auxiliary electrode AE and the preliminary electrodes PEa have similar shapes and are arranged at positions corresponding to each other, the difference in light-emitting characteristics between pixels may be reduced.

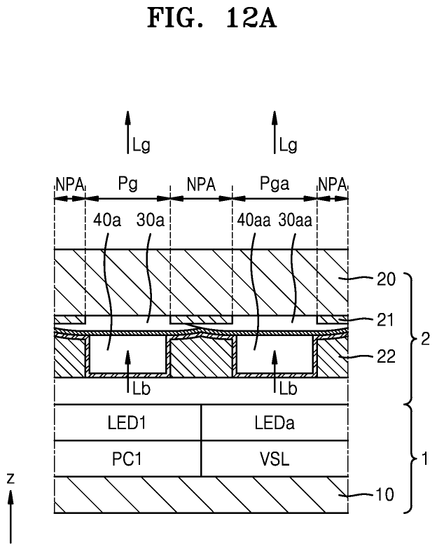

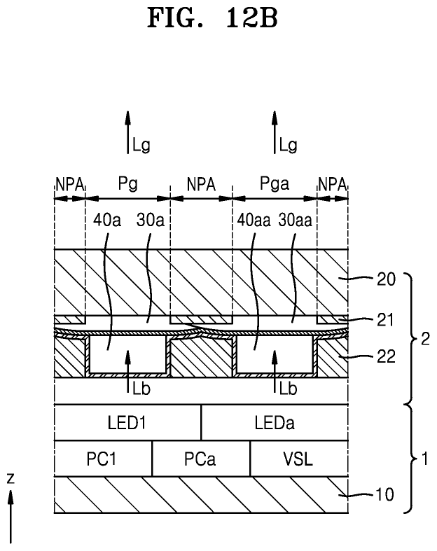

FIGS. 12A and 12B are schematic cross-sectional views of the display device DV according to embodiments. FIGS. 12A and 12B are for describing a cross-sectional structure of a green preliminary pixel Pga, the red pixel Pr and the blue pixel Pb described with reference to FIG. 2 are omitted.

Referring to FIG. 12A, the light-emitting panel 1 may include the first pixel circuit PC1, the common voltage line VSL, the first light-emitting diode LED1, and the preliminary light-emitting diode LEDa. The first pixel circuit PC1 may be disposed below the first light-emitting diode LED1, and the common voltage line VSL may be disposed below the preliminary light-emitting diode LEDa. The first pixel circuit PC1 may be electrically connected to the first light-emitting diode LED1 or the preliminary light-emitting diode LEDa. Only one of the first light-emitting diode LED1 and the preliminary light-emitting diode LEDa that is connected to the first pixel circuit PC1 may emit light, whereas a light-emitting diode that is not connected to the first pixel circuit PC1 may not emit light.

Light (e.g., blue light Lb) emitted from the first light-emitting diode LED1 or the preliminary light-emitting diode LEDa may be converted into the green light Lg or transmitted therethrough while passing through the color panel 2. An area overlapping the first light-emitting diode LED1 and from which the green light Lg is emitted may correspond to the green pixel Pg, and an area overlapping the preliminary light-emitting diode LEDa and from which the green light Lg is emitted may correspond to the green preliminary pixel Pga.

The color panel 2 may include a color conversion-transmission layer including the first color conversion portion 40a and a preliminary color conversion portion 40aa, and a color layer including the first color filter 30a and a preliminary color filter 30aa.

The first color area of the color panel 2 may include the first color conversion portion 40a and the first color filter 30a overlapping each other, and a preliminary color area may include the preliminary color conversion portion 40aa and the preliminary color filter 30aa overlapping each other.

The color panel 2 may include a light shielding area arranged to surround each of the first color area and the preliminary color area. The light shielding area may include the first light shielding layer 21 on the second substrate 20. After the first light shielding layer 21 is formed on the second substrate 20, the second substrate 20 may be flipped so that the first light shielding layer 21 is positioned between the first substrate 10 and the second substrate 20. In the specification, an element is disposed on the second substrate 20 indicates that the element is disposed on a side of the second substrate 20 facing the first substrate 10. The first light shielding layer 21 may include a plurality of holes formed as portions corresponding to the green pixel Pg and the green preliminary pixel Pga are removed. The first light shielding layer 21 may include the material portion located in the non-pixel area NPA. The light shielding area may include the second light shielding layer 22 on the first light shielding layer 21. The second light shielding layer 22 may also include the material portion located in the non-pixel area NPA.

The blue light Lb emitted from the first light-emitting diode LED1 of the light-emitting panel 1 may pass through the first color area of the color panel 2. While passing through the color panel 2, the blue light Lb may be converted and filtered into the green light Lg. The first color conversion portion 40a and the first color filter 30a provided in the first color area may be arranged to overlap the first light-emitting diode LED1. The blue light Lb emitted from the first light-emitting diode LED1 may be converted in the first color conversion portion 40a and then may pass through the first color filter 30a.

Likewise, the blue light Lb emitted from the preliminary light-emitting diode LEDa of the light-emitting panel 1 may pass through the preliminary color area of the color panel 2. While passing through the color panel 2, the blue light Lb may be converted and filtered into the green light Lg. The preliminary color conversion portion 40aa and the preliminary color filter 30aa provided in the preliminary color area may be arranged to overlap the preliminary light-emitting diode LEDa. The blue light Lb emitted from the preliminary light-emitting diode LEDa may be converted in the preliminary color conversion portion 40aa and then may pass through the preliminary color filter 30aa.

The preliminary color conversion portion 40aa may include quantum dots and scattering particles dispersed in photosensitive polymer, photosensitive polymer. The quantum dots may be excited by the blue light Lb and may isotropically emit the green light Lg having a wavelength greater than that of the blue light Lb. The scattering particles may scatter the blue light Lb that is not absorbed in the quantum dots so as to excite more quantum dots, thereby increasing color conversion efficiency.

The green light Lg converted by the preliminary color conversion portion 40aa may improve color purity while passing through the preliminary color filter 30aa. The preliminary color filter 30aa may include a pigment or dye of a first color (e.g., green).

Referring to FIG. 12B, the light-emitting panel 1 may include the first pixel circuit PC1, a preliminary pixel circuit PCa, the common voltage line VSL, the first light-emitting diode LED1, and the preliminary light-emitting diode LEDa. The preliminary pixel circuit PCa may be arranged below the first light-emitting diode LED1 and the preliminary light-emitting diode LEDa. The preliminary pixel circuit PCa may be arranged in a unit area where the first pixel circuit PC1, the second pixel circuit PC2, and the third pixel circuit PC3 are arranged.

In an embodiment, the first light-emitting diode LED1 may be electrically connected to the first pixel circuit PC1, and the preliminary light-emitting diode LEDa may be electrically connected to the preliminary pixel circuit PCa. In this case, the preliminary electrode PEa of the preliminary light-emitting diode LEDa may be in a state of being electrically connected to the preliminary pixel circuit PCa.

The preliminary pixel circuit PCa, which has been formed to not be electrically connected to some wires, may be electrically connected to the wires through laser irradiation and the like when a defect occurs in the green pixel Pg.

According to an embodiment configured as described above, by preventing the deterioration of visibility due to a defective display element, a display device for displaying a high quality image may be implemented. The scope of the disclosure is not limited by the above effects.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display device comprising:
a first substrate including a unit area in which a first pixel circuit, a second pixel circuit, and a third pixel circuit are arranged;
a first common voltage line and a second common voltage line arranged in parallel with the unit area therebetween;
an auxiliary electrode disposed on the first common voltage line and electrically connected to the first common voltage line; and
a preliminary electrode disposed on the second common voltage line.

2. The display device of claim 1, further comprising a pixel defining layer disposed on the auxiliary electrode and the preliminary electrode,
wherein an auxiliary opening exposing a part of the auxiliary electrode and a preliminary opening exposing a part of the preliminary electrode are defined in the pixel defining layer.

3. The display device of claim 2, further comprising:
an intermediate layer disposed on the pixel defining layer and in the auxiliary opening;
a counter electrode disposed on the intermediate layer; and
a through-hole extending through the intermediate layer in the auxiliary opening.

4. The display device of claim 3, wherein the counter electrode is electrically connected to the auxiliary electrode through the through-hole.

5. The display device of claim 3, wherein the intermediate layer comprises an emission layer arranged to correspond to the preliminary electrode.

6. The display device of claim 5, wherein the emission layer and the auxiliary electrode are disposed on mutually exclusive parts of the first substrate.

7. The display device of claim 1, further comprising a first pixel electrode arranged in the unit area,
wherein the first pixel circuit is electrically connected to one of the first pixel electrode and the preliminary electrode.

8. The display device of claim 7, wherein an area of the first pixel electrode is greater than an area of the preliminary electrode.

9. The display device of claim 1, wherein an area of the preliminary electrode is greater than an area of the auxiliary electrode.

10. The display device of claim 1, wherein the auxiliary electrode and the preliminary electrode are each provided in plural, and
one or more preliminary electrodes are arranged between two neighboring auxiliary electrodes.

11. The display device of claim 1, further comprising an auxiliary common voltage line electrically connected to the first common voltage line and the second common voltage line and disposed on the first common voltage line and the second common voltage line.

12. The display device of claim 11, wherein the first common voltage line and the second common voltage line extend in a first direction,
the auxiliary common voltage line extends in a second direction crossing the first direction, and
the first common voltage line and the second common voltage line form a mesh structure with the auxiliary common voltage line.

13. The display device of claim 1, further comprising:
a first pixel electrode electrically connected to the first pixel circuit; and
a preliminary pixel circuit arranged in the unit area.

14. The display device of claim 13, wherein the preliminary electrode is electrically connected to the preliminary pixel circuit.

15. A display device comprising:
a light-emitting panel including light-emitting diodes; and
a color panel disposed on the light-emitting panel and converting or transmitting light emitted from the light-emitting diodes,
wherein the light-emitting panel comprises:
a first substrate including a unit area in which a first pixel circuit, a second pixel circuit, and a third pixel circuit are arranged;
a first common voltage line and a second common voltage line arranged in parallel with the unit area therebetween;
an auxiliary electrode disposed on the first common voltage line and electrically connected to the first common voltage line; and
a preliminary electrode disposed on the second common voltage line.

16. The display device of claim 15, further comprising a pixel defining layer disposed on the auxiliary electrode and the preliminary electrode,
wherein an auxiliary opening exposing a part of the auxiliary electrode and a preliminary pixel opening exposing a part of the preliminary electrode are defined in the pixel defining layer.

17. The display device of claim 16, further comprising:
an intermediate layer disposed on the pixel defining layer;
a counter electrode disposed on the intermediate layer; and
a through-hole extending through the intermediate layer in the auxiliary opening.

18. The display device of claim 17, wherein the counter electrode is electrically connected to the auxiliary electrode through the through-hole.

19. The display device of claim 16, further comprising a first pixel electrode arranged in the unit area,
wherein the first pixel circuit is electrically connected to the first pixel electrode or the preliminary electrode.

20. The display device of claim 19, wherein the color panel comprises:
a second substrate;
a first color conversion portion disposed on the second substrate and arranged to correspond to the first pixel electrode; and
a preliminary color conversion portion arranged to correspond to the preliminary electrode, and
the first color conversion portion and the preliminary color conversion portion convert incident blue light into green light.
